(19) United States
(12) Patent Application Publication
(10) Pub. No.: US 2026/0113911 A1
(43) Pub. Date: Apr. 23, 2026

(54) POWER SEMICONDUCTOR DEVICE

(71) Applicant: MITSUBISHI ELECTRIC CORPORATION, Tokyo (JP)

(72) Inventors: Tatsushi MORISADA, Tokyo (JP); Yasuyuki SANDA, Tokyo (JP); Kenichi HAYASHI, Tokyo (JP)

(73) Assignee: MITSUBISHI ELECTRIC CORPORATION, Tokyo (JP)

(21) Appl. No.: 19/486,045

(22) PCT Filed: Jul. 27, 2023
(86) PCT No.: PCT/JP2023/027643

§ 371 Date: Nov. 20, 2025

(51) Int. Cl. H05K 7/20; H10W 40/20

(52) U.S. Cl. CPC H05K 7/209; H10W 40/235

(57) ABSTRACT

A power semiconductor device includes a case including an air passage; a heat sink held by the case, with a plurality of fins disposed in the air passage; and a plurality of power modules. An uneven surface is formed on an opposite face of a heat sink base. The power modules each include an uneven part engaging with the uneven surface of the heat sink base and are spaced along a direction of an air flow, with the uneven parts fitted into the uneven surface of the heat sink base. One of an adjacent pair of the power modules in the direction of the air flow is disposed to offset in a direction orthogonal to the direction of the air flow relative to an other of the adjacent pair of the power modules.

### FIELD

The present disclosure relates to a power semiconductor device equipped with a heat sink and power modules.

### BACKGROUND

A conventionally known power semiconductor device is equipped with a heat sink and power modules. For example, a power semiconductor device disclosed in Patent Literature 1 includes a heat sink that includes a base and a plurality of fins arranged in parallel at intervals on one face of the base and a plurality of power semiconductor modules provided on an opposite face of the base. The power semiconductor device described in Patent Literature 1 reduces temperature increase in the power semiconductor modules by blowing cooling air along the arrayed fins of the heat sink. The plurality of power semiconductor modules are aligned obliquely to a direction of the cooling air flow so that a downstream power semiconductor module is not affected by heat generated by an upstream power semiconductor module.

### CITATION LIST

### Patent Literature

Patent Literature 1: Japanese Patent Application Laid-open No. 2011-66123

### SUMMARY OF INVENTION

### Problem to be solved by the Invention

However, since the plurality of power semiconductor modules are aligned obliquely to the direction of the cooling air flow, given a power semiconductor module installation area of the base, the power semiconductor device disclosed in Patent Literature 1 makes it difficult to arrange the power semiconductor modules with sufficient spacing, leaving a possibility that the downstream power semiconductor module could be affected by the heat generated by the upstream power semiconductor module.

The present disclosure has been made in view of the above, and an object of the present disclosure is to obtain a power semiconductor device in which downstream power semiconductor modules are less likely to be affected by heat generated by upstream power semiconductor modules.

### Means to Solve the Problem

In order to solve the above-mentioned problem and achieve the object, a power semiconductor device according to the present disclosure includes: a case including an air passage, with an inlet and an outlet for an air flow facing each other; a heat sink including a plate-shaped heat sink base; and a plurality of plate-shaped fins arranged in parallel at intervals on one face of the heat sink base, the heat sink being held by the case, with the plurality of fins disposed in the air passage; and a plurality of power modules provided on an opposite face of the heat sink base. An uneven surface is formed on the opposite face of the heat sink base. The power modules each includes an uneven part engaging with the uneven surface of the heat sink base and are spaced along a direction of the air flow, with the uneven parts fitted into the uneven surface of the heat sink base. One of an adjacent pair of the power modules in the direction of the air flow is disposed to offset in a direction orthogonal to the direction of the air flow relative to an other of the adjacent pair of the power modules.

### Effect of the Invention

An effect of the power semiconductor device according to the present disclosure is that downstream power semiconductor modules are less likely to be affected by heat generated by upstream power semiconductor modules.

### BRIEF DESCRIPTION OF DRAWINGS

FIG. 1 is a plan view illustrating a power semiconductor device according to a first embodiment.

FIG. 2 is a cross-sectional view in the direction of arrows II-II in FIG. 1.

FIG. 3 is a cross-sectional view in the direction of arrows III-III in FIG. 1.

FIG. 4 is a plan view illustrating a power semiconductor device according to Comparative Example 1.

FIG. 5 is a cross-sectional view in the direction of arrows V-V in FIG. 4.

FIG. 6 is a contour diagram illustrating temperature distribution of air that flows from an inlet to an outlet of the power semiconductor device according to Comparative Example 1.

FIG. 7 is a contour diagram illustrating temperature distribution of air that flows from an inlet to an outlet of the power semiconductor device according to the first embodiment.

FIG. 8 is a plan view illustrating a power semiconductor device according to Comparative Example 2.

FIG. 9 is a cross-sectional view in the direction of arrows IX-IX in FIG. 8.

FIG. 10 is a cross-sectional view in the direction of arrows X-X in FIG. 8.

FIG. 11 is a plan view of the power semiconductor device according to the first embodiment, illustrating Variation 1 of its uneven surface.

FIG. 12 is a plan view of the power semiconductor device according to the first embodiment, illustrating Variation 2 of its uneven surface.

FIG. 13 is a plan view of the power semiconductor device according to the first embodiment, illustrating Variation 3 of its uneven surface.

FIG. 14 is a plan view illustrating a power semiconductor device according to a second embodiment.

FIG. 15 is a cross-sectional view in the direction of arrows XV-XV in FIG. 14.

FIG. 16 is a cross-sectional view in the direction of arrows XVI-XVI in FIG. 14.

FIG. 17 is a plan view illustrating an adapter plate of the power semiconductor device according to the second embodiment.

FIG. 18 is a plan view illustrating a power semiconductor device according to a third embodiment.

FIG. 19 is a cross-sectional view in the direction of arrows XIX-XIX in FIG. 18.

FIG. 20 is a plan view illustrating an adapter plate of the power semiconductor device according to the third embodiment.

FIG. 21 is a plan view illustrating a variation of the power semiconductor device according to the third embodiment.

FIG. 22 is a plan view illustrating an adapter plate of the variation of the power semiconductor device according to the third embodiment.

FIG. 23 is a longitudinal sectional view schematically illustrating a power semiconductor device according to a fourth embodiment.

FIG. 24 is a longitudinal sectional view schematically illustrating Variation 1 of the power semiconductor device according to the fourth embodiment.

FIG. 25 is a longitudinal sectional view schematically illustrating Variation 2 of the power semiconductor device according to the fourth embodiment.

### DESCRIPTION OF EMBODIMENTS

With reference to the drawings, a detailed description is hereinafter provided of power semiconductor devices according to embodiments of the present disclosure.

### First Embodiment

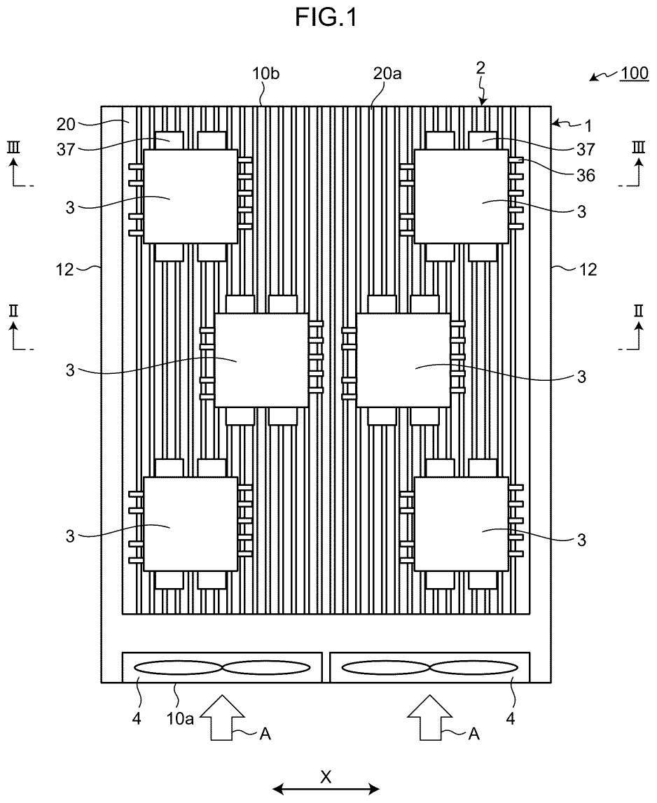

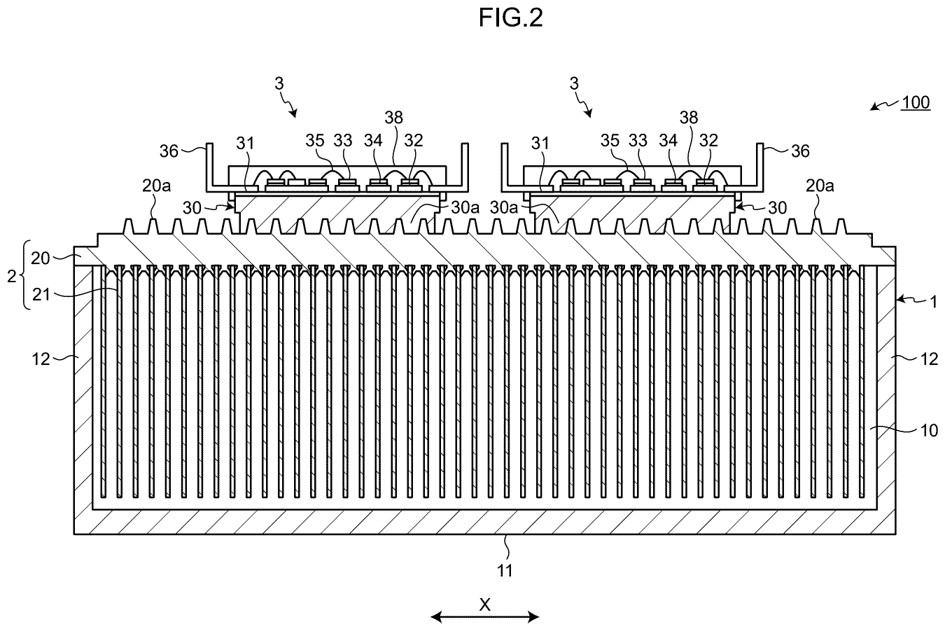

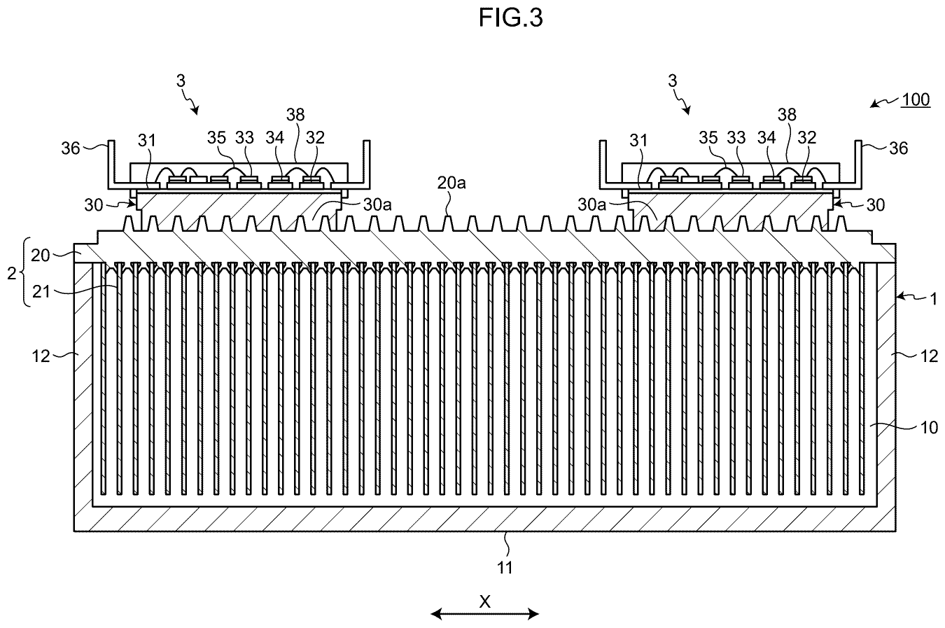

FIG. 1 is a plan view of a power semiconductor device according to a first embodiment. White arrows illustrated in FIG. 1 indicate a direction of an air flow A. FIG. 2 is a cross-sectional view in the direction of arrows II-II in FIG. 1. FIG. 3 is a cross-sectional view in the direction of arrows III-III in FIG. 1. In the cross-sectional views, some hatching is omitted to make component parts of power modules 3 easier to see.

As illustrated in FIGS. 1 to 3, the power semiconductor device 100 according to the first embodiment includes a case 1, a heat sink 2, the plurality of power modules 3, and cooling fans 4.

As illustrated in FIGS. 1 to 3, the case 1 defines an air passage 10, with an inlet 10a and an outlet 10b for the air flow A facing each other. The case 1 also holds heat sink-integrated power modules in which the plurality of power modules 3 are integrated with the heat sink 2. The case 1 has a recessed shape formed by a bottom part 11 and a pair of side walls 12. The case 1 has open ends extending along the direction of the air flow A. One of the open ends serves as the inlet 10a for the air flow A, and the other open end serves as the outlet 10b for the air flow A. The air passage 10 is a space surrounded by the bottom part 11 and the pair of side walls 12. In the example illustrated in FIG. 1, the direction of the air flow A is from the inlet 10a to the outlet 10b; however, this is not limiting. The air flow A may be in an opposite direction, from the outlet 10b to the inlet 10a, with the outlet 10b serving as an inlet and the inlet 10a, where the cooling fans 4 are disposed, serving as an outlet.

The case 1 is formed of a plated steel plate. The plated steel plate is rigid enough to hold the heat sink-integrated power modules and is a material that allows for thickness reduction and weight reduction. The case 1 may be formed of a material other than a plated steel plate.

The heat sink 2 is integrated with the plurality of power modules 3 and dissipates heat generated by the power modules 3. As illustrated in FIGS. 2 and 3, the heat sink 2 includes a plate-shaped heat sink base 20 and a plurality of plate-shaped fins 21 arranged in parallel at intervals on one face of the heat sink base 20. The heat sink 2 is, for example, a crimped heat sink in which the heat sink base 20 and the fins 21 are integrated by “crimping”. The heat sink 2 is held by the case 1, with the plurality of fins 21 disposed in the air passage 10.

The heat sink base 20 is, for example, rectangular in shape. The heat sink base 20 is formed of a metal material with relatively high thermal conductivity so as to efficiently transfer the heat generated by the power modules 3 to the fins 21. For example, the heat sink base 20 is formed of a corrosion-resistant metal material, such as aluminum or an aluminum alloy. The heat sink base 20 is manufactured by a processing method such as machining, die casting, forging, or extrusion.

An opposite face of the heat sink base 20 includes an uneven surface 20a formed in an area where the plurality of power modules 3 are provided. The uneven surface 20a includes recesses and projections that extend along the direction of the air flow A. The area where the plurality of power modules 3 are provided refers, for example, to the entire opposite face of the heat sink base 20.

The heat sink base 20 has peripheral edges placed on upper end faces of the side walls 12, with the plurality of fins 21 housed inside the case 1 having the recessed shape, and is fixed to the side walls 12 by joining members (not illustrated), such as screws. The side walls 12 are provided with threaded holes (not illustrated) for the screws or other joining members to be screwed in. The heat sink base 20 is provided with threaded or through holes (not illustrated) at positions corresponding to the threaded holes in the side walls 12.

Each of the fins 21 is a heat dissipation component formed of a thin rectangular plate. The fins 21 are formed of a metal material with relatively high thermal conductivity so as to dissipate the heat generated by the power modules 3. For example, the fins 21 are formed of a corrosion-resistant metal material, such as aluminum or an aluminum alloy. Using rolled aluminum or another rolled metal material for the fins 21 enables both machinability and heat dissipation of the fins 21 to be achieved.

Each of the plurality of fins 21 is inserted into a fin insertion groove (not illustrated) formed on the one face of the heat sink base 20 and is fixed to the heat sink base 20 by crimping. When the heat sink 2 is the crimped heat sink, the absence of aspect ratio constraints in die casting and extrusion allows for freedom in designing the fins 21 and improved heat dissipation performance. However, the heat sink 2 is not limited to a crimped heat sink and may be manufactured by another processing method. For example, the heat sink 2 may be one in which the fins 21 and the heat sink base 20 are integrally manufactured by extrusion or die casting. The heat sink 2 used in the heat sink-integrated power modules may be manufactured by machining or forging.

Each of the power modules 3 is a power semiconductor module of a resin mold type. As illustrated in FIG. 1, the plurality of power modules 3 are spaced along the direction of the air flow A. The power modules 3 installed in the power semiconductor device 100 illustrated in FIG. 1 are six in number and are, for example, in a two-column-by-three-row arrangement. The power modules 3 are not limited to the six illustrated; there only need to be at least two spaced along the direction of the air flow A.

As illustrated in FIG. 1, in the power semiconductor device 100 according to the first embodiment, one of an adjacent pair of the power modules 3 in the direction of the air flow A is disposed to offset in a direction X orthogonal to the direction of the air flow A relative to the other of the adjacent pair of the power modules 3. Specifically, among three power modules 3 provided along the direction of the air flow A, the middle power module 3 is disposed to offset in the direction X, which is orthogonal to the direction of the air flow A, relative to the most upstream power module 3 and the most downstream power module 3.

As illustrated in FIGS. 1 to 3, each power module 3 includes a fin base 30, an insulator 31, metal conductors 32, semiconductor elements 33, a bonding material 34, wires 35, control terminals 36, main terminals 37, and an encapsulant 38.

The fin base 30 is a rectangular plate smaller than the heat sink base 20 and serves as a connection component that connects the power module 3 to the heat sink 2. The fin base 30 is formed of a metal material with relatively high thermal conductivity so as to efficiently transfer heat generated by the power module 3 to the heat sink 2. For example, the fin base 30 is formed of a corrosion-resistant metal material, such as aluminum or an aluminum alloy. The fin base 30 is manufactured by a processing method such as machining, die casting, forging, or extrusion.

The fin base 30 includes an uneven part 30a formed on a face facing the heat sink base 20. The uneven part 30a engages with the uneven surface 20a of the heat sink base 20. Each power module 3 is integrated with the heat sink 2 by press-fitting the uneven part 30a of the fin base 30 and the uneven surface 20a of the heat sink base 20 together. The power modules 3 are installed with their arrangement freely changeable within the area where the uneven surface 20a is formed. Each power module 3 is a grease-less power module that does not use thermally conductive grease between the power module 3 and the heat sink 2. Compared with power modules that use thermally conductive grease, the grease-less power module enables improved heat dissipation performance for the heat generated by the power module 3 and, therefore, is suitably used in power semiconductor devices with larger power capacity. Furthermore, since the power semiconductor device 100 does not use thermally conductive grease, replacement of the power modules 3 does not require processes such as removal and reapplication of the thermally conductive grease, allowing for better productivity and maintainability.

The respective materials of the heat sink base 20, each fin 21, and the fin base 30 are not limited to the above-mentioned aluminum materials and may be other materials. In other words, a material combination different from the above material combination may be used for the heat sink base 20, the fins 21, and the fin base 30. For example, using copper plate components that have a higher thermal conductivity than the aluminum material for the fins 21 further improves the heat dissipation performance of the fins 21 compared to when the fins 21 are plate components formed of the aluminum material.

The insulator 31 is an insulating sheet with heat dissipation properties. The insulator 31 is fixed to an opposite face of the fin base 30. The insulator 31 provides insulation between the component parts of the power module 3, which are enclosed by the encapsulant 38, and the heat sink base 20 and dissipates heat generated by the semiconductor elements 33 into the heat sink base 20. The heat dissipation properties of the insulator 31 are equivalent to or better than those of the encapsulant 38.

Each of the metal conductors 32 is a substrate on which the semiconductor element 33 is mounted and dissipates heat generated by the semiconductor element 33 into the insulator 31.

Each semiconductor element 33 is a semiconductor device used for power control. Examples of the semiconductor element 33 include a rectifier diode, a power transistor, a thyristor, and an insulated-gate bipolar transistor (IGBT). Each semiconductor element 33 is exemplified by a device formed of silicon (Si) or by a device formed of a wide-bandgap semiconductor having a larger bandgap than silicon. The wide-bandgap semiconductor is, for example, silicon carbide (Sic), a gallium nitride material, or diamond. By using the wide-bandgap semiconductor, the semiconductor element 33 has a higher allowable current density and lower power loss and, therefore, allows for size reduction of the power module 3, which in turn enables size reduction of the heat sink 2 and the power semiconductor device 100.

The bonding material 34 is, for example, solder and bonds the metal conductors 32 and the semiconductor elements 33 together. Using the bonding material 34, the semiconductor elements 33 are die-bonded to the metal conductors 32, respectively. The bonding material 34 is not limited to solder and may be composed differently.

The wires 35 electrically connect the semiconductor elements 33. The wires 35 also electrically connect the semiconductor elements 33 and the main terminals 37.

The control terminals 36 and the main terminals 37 are connected to the semiconductor elements 33 to supply power to the semiconductor elements 33 or transmit signals between the semiconductor elements 33 and an external device.

The encapsulant 38 is formed of, for example, a thermosetting resin such as epoxy and ensures insulation between the component parts of the power module 3. The encapsulant 38 is, for example, a transfer mold formed by transfer molding. However, the encapsulant 38 is not limited to a thermosetting resin. Furthermore, the method of molding the encapsulant 38 is not limited to transfer molding.

The cooling fans 4 generate the air flow A in the direction from the inlet 10a to the outlet 10b of the case 1. The cooling fans 4 are installed at the inlet 10a of the case 1. A means for attaching the cooling fans 4 to the case 1 may involve providing a fan mounting structure in a part of the case 1 for the attachment of the cooling fans 4 or providing a mounting member separate from the case 1 at the inlet 10a for the attachment of the cooling fans 4.

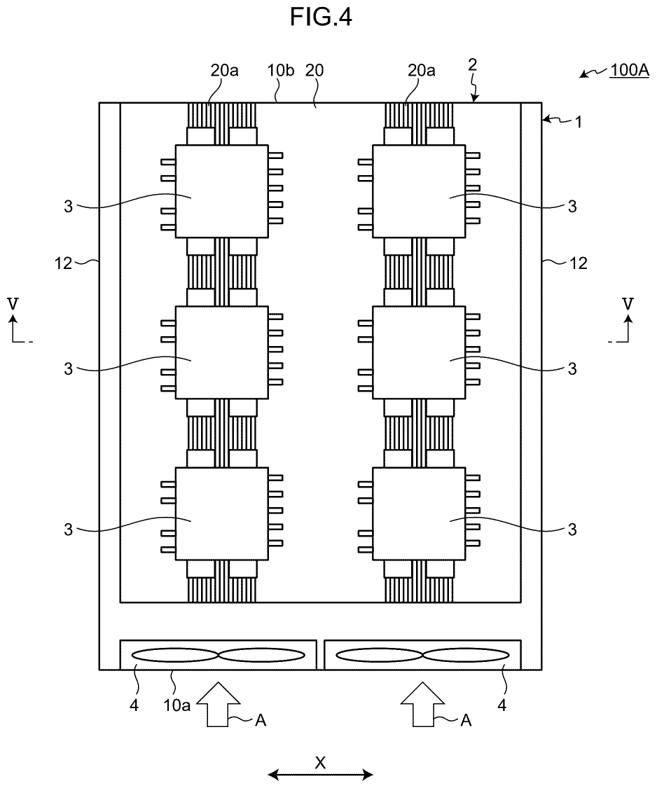

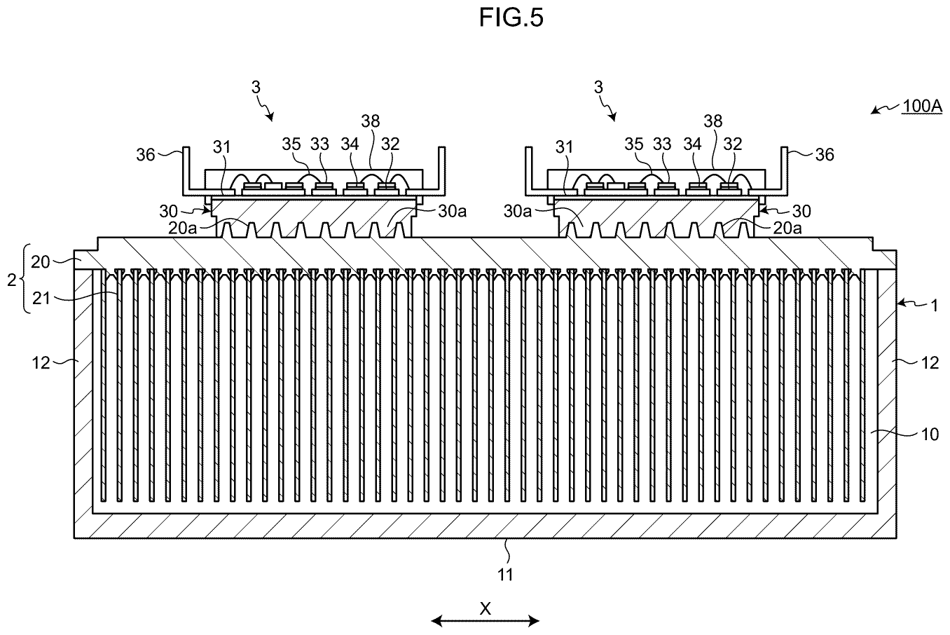

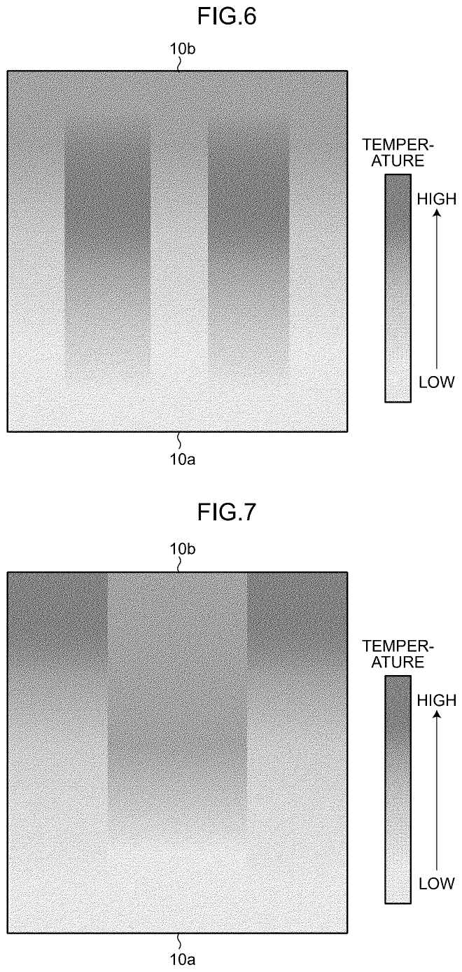

FIG. 4 is a plan view illustrating a power semiconductor device according to Comparative Example 1. FIG. 5 is a cross-sectional view in the direction of arrows V-V in FIG. 4. FIG. 6 is a contour diagram illustrating temperature distribution of air that flows from an inlet to an outlet of the power semiconductor device according to Comparative Example 1.

In the power semiconductor device 100A according to Comparative Example 1 illustrated in FIGS. 4 and 5, the plurality of power modules 3 are spaced along the direction of the air flow A. The power modules 3 are, for example, in a two-column-by-three-row arrangement and are aligned along the direction of the air flow A. In this case, as illustrated in FIG. 6, the air that flows between the fins 21 of a heat sink 2 from an upstream side to a downstream side experiences a continuous increase in temperature. In other words, because the semiconductor elements 33 of the downstream power modules 3 are affected by heat generated by the semiconductor elements 33 of the upstream power modules 3, temperature of the downstream power modules 3 increases due to thermal interference.

On the other hand, in the power semiconductor device 100 according to the first embodiment, as illustrated in FIG. 1, one of an adjacent pair of the power modules 3 in the direction of the air flow A is disposed to offset in the direction X, which is orthogonal to the direction of the air flow A, relative to the other of the adjacent pair of the power modules 3. Specifically, among three power modules 3 provided along the direction of the air flow A, the middle power module 3 is disposed to offset in the direction X, which is orthogonal to the direction of the air flow A, relative to the most upstream power module 3 and the most downstream power module 3.

FIG. 7 is a contour diagram illustrating temperature distribution of air that flows from the inlet to the outlet of the power semiconductor device according to the first embodiment. As illustrated in FIG. 7, the power semiconductor device 100 according to the first embodiment can reduce cumulative thermal interference and, therefore, makes it less likely for the semiconductor elements 33 of the downstream power modules 3 to be affected by heat generated by the semiconductor elements 33 of the upstream power modules 3, thus enabling the lower-temperature air to be supplied downstream. Therefore, the power semiconductor device 100 according to the first embodiment can effectively suppress the temperature increase in the power modules 3.

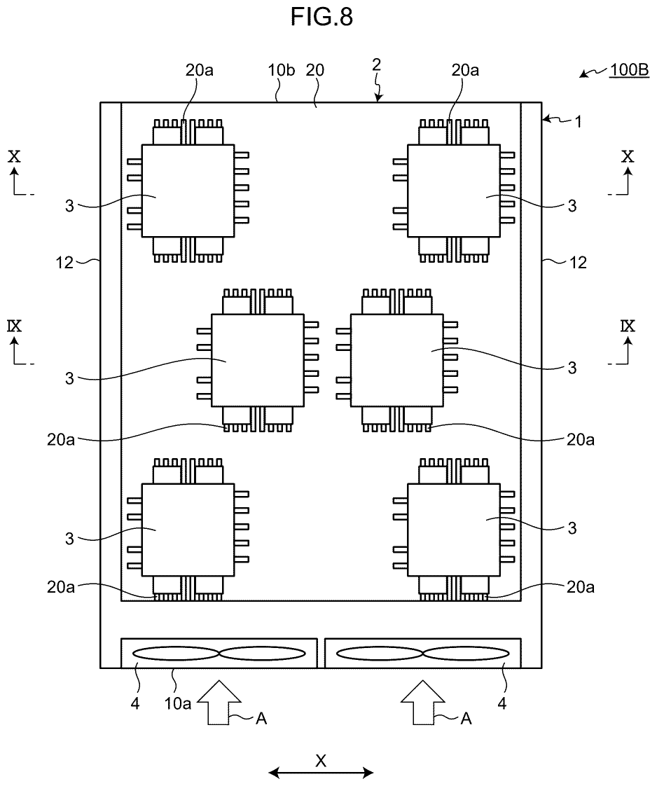

FIG. 8 is a plan view illustrating a power semiconductor device according to Comparative Example 2.

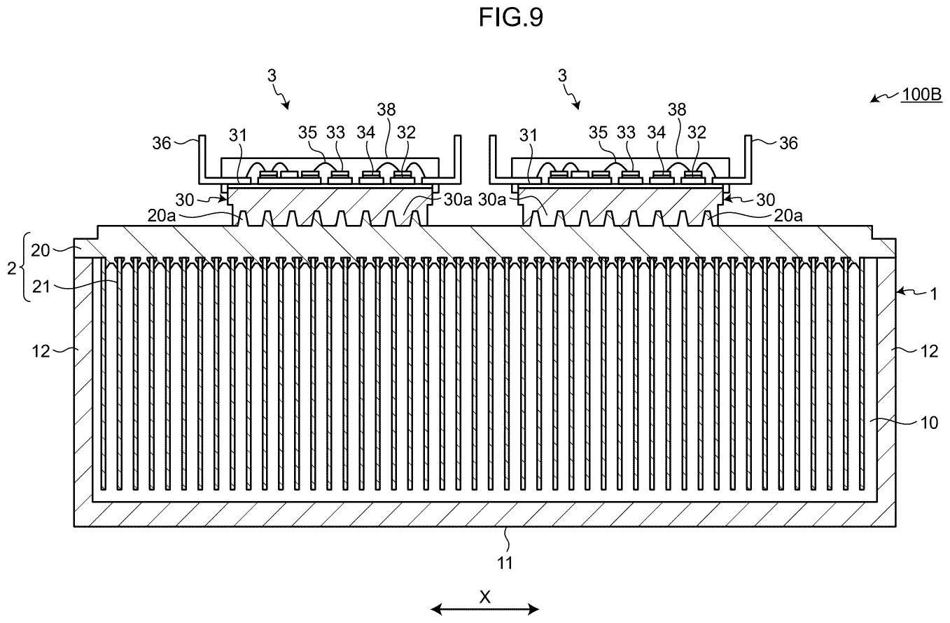

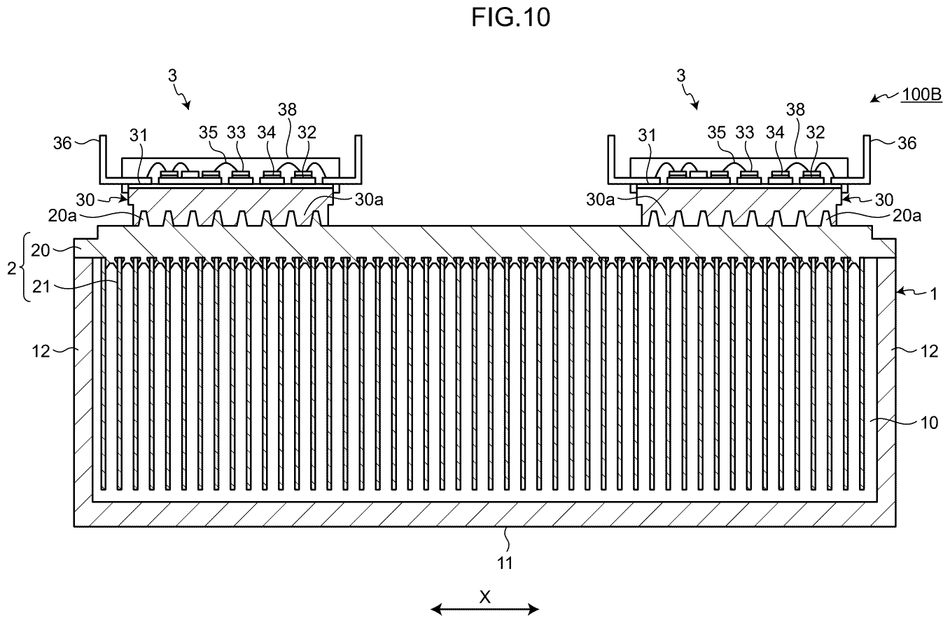

FIG. 9 is a cross-sectional view in the direction of arrows IX-IX in FIG. 8. FIG. 10 is a cross-sectional view in the direction of arrows X-X in FIG. 8.

In the power semiconductor device 100B according to Comparative Example 2 illustrated in FIGS. 8 to 10, a plurality of uneven surfaces 20a corresponding respectively to the power modules 3 are formed on an opposite face of a heat sink base 20. Each of the uneven surfaces 20a includes recesses and projections that extend along the direction of the air flow A. Each power module 3 includes the fin base 30 that has the uneven part 30a engaging with the corresponding uneven surface 20a of the heat sink base 20. In the power semiconductor device 100B, positions of the power modules 3 to be installed on the heat sink base 20 are determined during a design stage of the uneven surfaces 20a. Therefore, when the power modules 3 need to be rearranged after the design, a new heat sink base 20 needs to be manufactured.

On the other hand, in the power semiconductor device 100 according to the first embodiment, as illustrated in FIG. 1, the uneven surface 20a is formed on the opposite face of the heat sink base 20. Each power module 3 includes the fin base 30 that has the uneven part 30a engaging with the uneven surface 20a of the heat sink base 20. In other words, the power semiconductor device 100 according to the first embodiment enables the power modules 3 to be freely arranged within the area where the uneven surface 20a of the heat sink base 20 is formed, thus allowing for greater design freedom and enhanced productivity of the heat sink-integrated power modules.

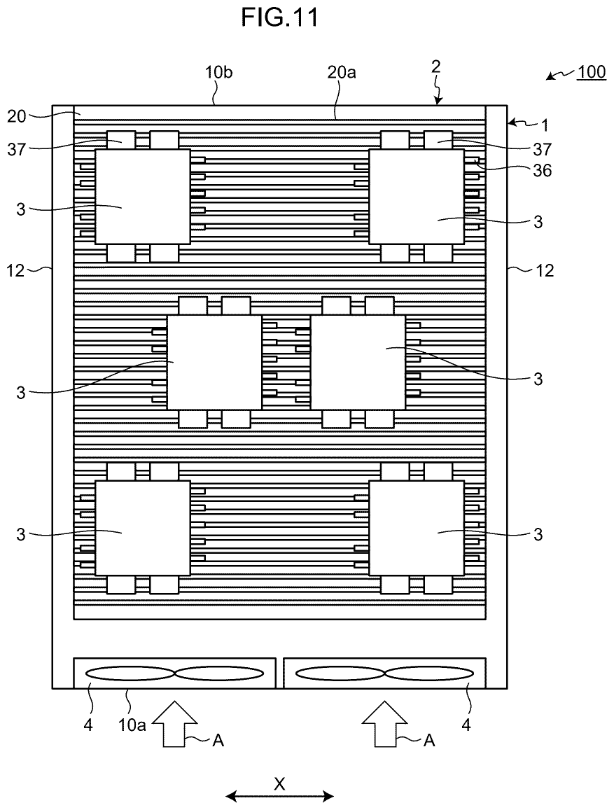

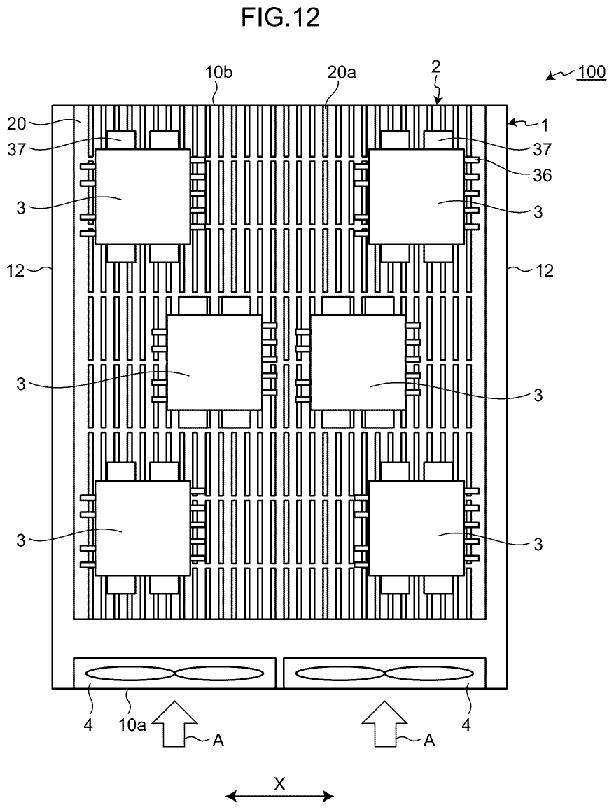

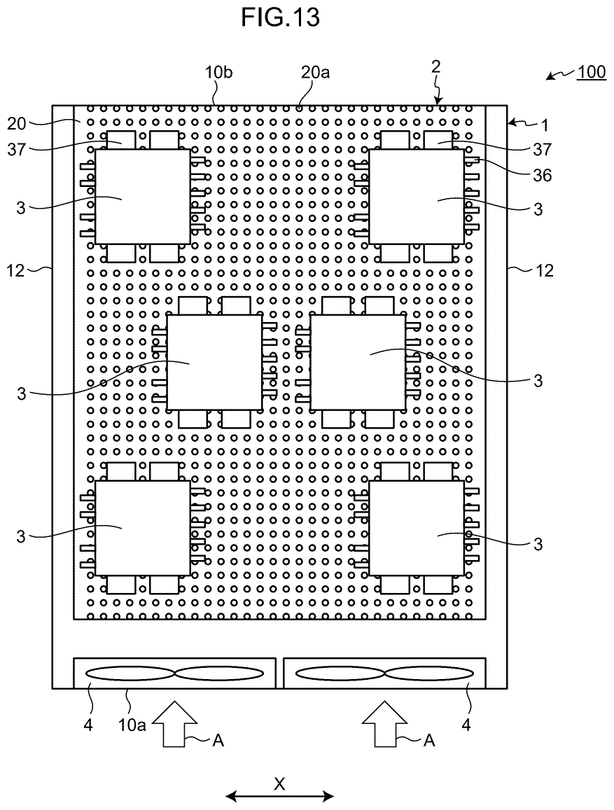

FIG. 11 is a plan view of the power semiconductor device according to the first embodiment, illustrating Variation 1 of its uneven surface. FIG. 12 is a plan view of the power semiconductor device according to the first embodiment, illustrating Variation 2 of its uneven surface. FIG. 13 is a plan view of the power semiconductor device according to the first embodiment, illustrating Variation 3 of its uneven surface. The uneven surface 20a of the heat sink base 20 is not limited to the configuration illustrated in FIG. 1 in which the recesses and the projections extend along the direction of the air flow A. As illustrated in FIG. 11, the uneven surface 20a may be formed so that its recesses and projections extend in a direction intersecting the direction of the air flow A, for example, in the direction orthogonal to the direction of the air flow A. The recesses and the projections are not limited to the continuously formed structures illustrated in FIG. 1 and may each be formed at intervals along their extending direction, as illustrated in FIG. 12. The uneven surface 20a may, for example, be configured with dot-shaped protrusions arranged in rows, as illustrated in FIG. 13, or may have another configuration. In short, the uneven surface 20a only needs to be configured to engage with the uneven parts 30a of the power modules 3. Shapes, orientations, and the formation area of the recesses and the projections may be appropriately modified according to how the power semiconductor device 100 is configured. In this case, the uneven parts 30a of the power modules 3 are formed in accordance with the configuration of the uneven surface 20a.

### Second Embodiment

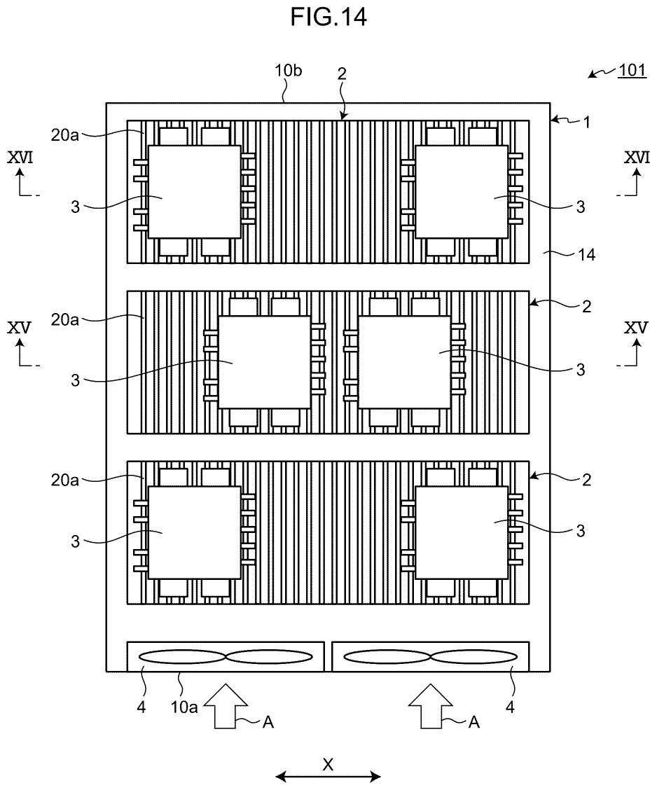

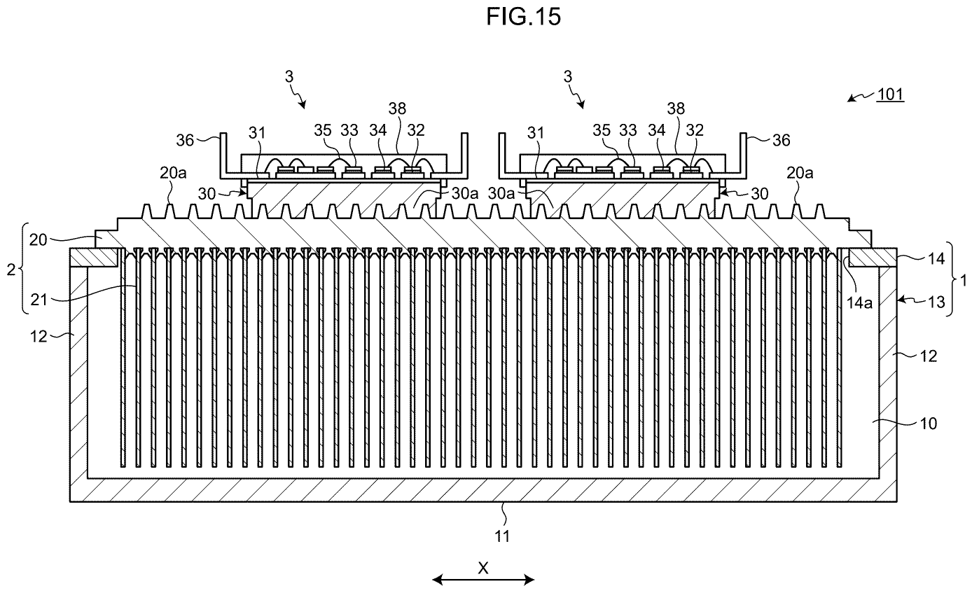

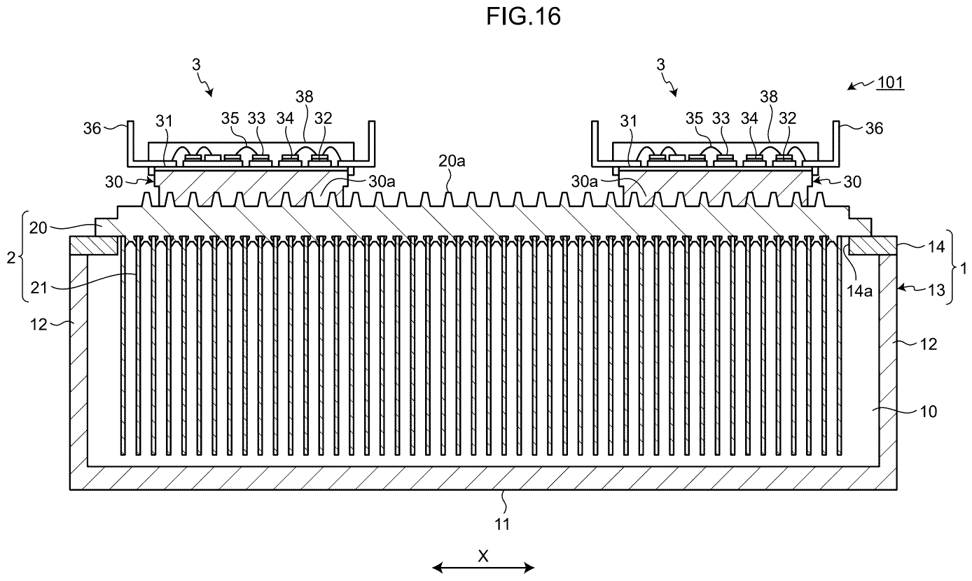

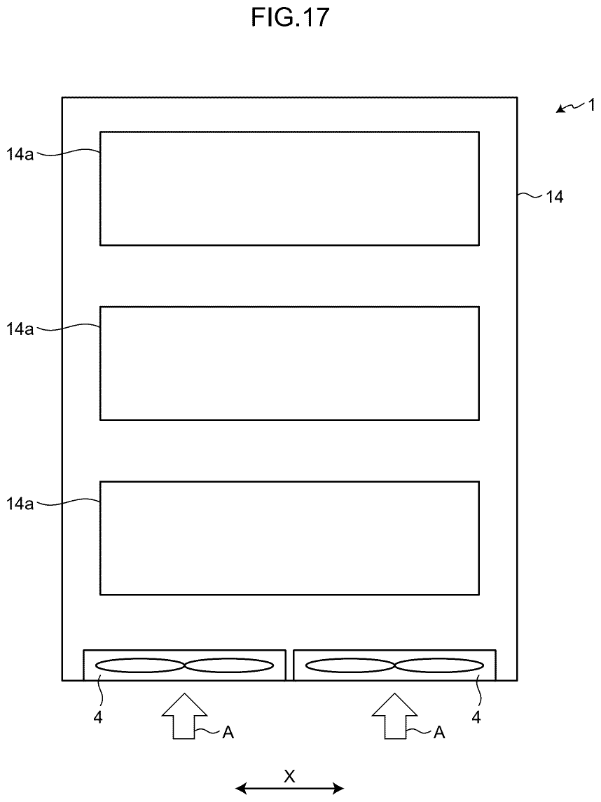

Next, a description of a power semiconductor device 101 according to a second embodiment is provided. FIG. 14 is a plan view illustrating the power semiconductor device according to the second embodiment. FIG. 15 is a cross-sectional view in the direction of arrows XV-XV in FIG. 14. FIG. 16 is a cross-sectional view in the direction of arrows XVI-XVI in FIG. 14. FIG. 17 is a plan view illustrating an adapter plate of the power semiconductor device according to the second embodiment. In the cross-sectional views, some hatching is omitted to make the Component parts of the power modules 3 easier to see.

As illustrated in FIGS. 14 to 16, a case 1 of the power semiconductor device 101 according to the second embodiment has a configuration in which a plurality of openings 14a are formed at intervals along the direction of the air flow A in a face defining the air passage 10. Specifically, the case 1 includes a housing 13 that has a recessed shape formed by the bottom part 11 and the pair of side walls 12; and the adapter plate 14 that is disposed facing the bottom part 11 and covers an open face of the housing 13. The case 1, formed by the housing 13 and the adapter plate 14, has the shape of a rectangular tube. The case 1 has open ends extending along the direction of the air flow A. One of the open ends serves as the inlet 10a for the air flow A, which is blown by the cooling fans 4, and the other open end serves as the outlet 10b for the air flow A. The air passage 10 is a space surrounded by the housing 13 and the adapter plate 14. In the example illustrated in FIG. 14, the direction of the air flow A is from the inlet 10a to the outlet 10b; however, this is not limiting. The air flow A may be in an opposite direction, from the outlet 10b to the inlet 10a, with the outlet 10b serving as an inlet and the inlet 10a, where the cooling fans 4 are disposed, serving as an outlet.

The housing 13 and the adapter plate 14 are each formed of a plated steel plate. The plated steel plate is rigid enough to hold the heat sink-integrated power modules and is a material that allows for thickness reduction and weight reduction. The housing 13 and the adapter plate 14 may each be formed of a material other than a plated steel plate.

The adapter plate 14 has peripheral edges placed on the upper end faces of the side walls 12 and is fixed to the side walls 12 by joining members (not illustrated), such as screws. The side walls 12 are provided with threaded holes (not illustrated) for the screws or other joining members to be screwed in. The adapter plate 14 is provided with threaded or through holes (not illustrated) at positions corresponding to the threaded holes in the side walls 12.

As illustrated in FIG. 17, the openings 14a, which are three in number and of the same shape and size, are formed in the adapter plate 14 and aligned at intervals along the direction of the air flow A. In a plan view of the power semiconductor device 101, each of the openings 14a has, for example, a rectangular shape that is elongated in the direction X, which is orthogonal to the direction of the air flow A.

As illustrated in FIG. 14, heat sinks 2 are provided as individual pieces corresponding respectively to the openings 14a. As illustrated in FIGS. 15 and 16, each of the heat sinks 2 is supported by the case 1, with its fins 21 inserted through the opening 14a and disposed in the air passage 10. Each heat sink 2 is formed in accordance with the size and shape of the opening 14a. Each heat sink base 20 has its peripheral edges placed on an upper face of the adapter plate 14, with the fins 21 inserted through the opening 14a and disposed in the air passage 10, and is fixed to the adapter plate 14 by joining members (not illustrated), such as screws. The adapter plate 14 is provided with threaded holes (not illustrated) for the screws or other joining members to be screwed in. Each heat sink base 20 is provided with threaded or through holes (not illustrated) at positions corresponding to the threaded holes in the adapter plate 14.

Each of the heat sinks 2 that are individually provided is integrally provided with two power modules 3 arranged side by side. In other words, the power semiconductor device 101 according to the second embodiment is configured by omitting part of the heat sink 2 from the configuration of the first embodiment, thereby enabling weight reduction of the device. Furthermore, the power semiconductor device 101 according to the second embodiment allows for improved maintainability because when a power module 3 fails, only the heat sink 2 on which the failed power module 3 is mounted needs to be replaced.

In the power semiconductor device 101 according to the second embodiment as well, one of an adjacent pair of the power modules 3 in the direction of the air flow A is disposed to offset in the direction X, which is orthogonal to the direction of the air flow A, relative to the other of the adjacent pair of the power modules 3.

Specifically, among three power modules 3 provided along the direction of the air flow A, the middle power module 3 is disposed to offset in the direction X, which is orthogonal to the direction of the air flow A, relative to the most upstream power module 3 and the most downstream power module 3.

With this configuration, the power semiconductor device 101 according to the second embodiment can reduce cumulative thermal interference and, therefore, makes it less likely for the semiconductor elements 33 of the downstream power modules 3 to be affected by heat generated by the semiconductor elements 33 of the upstream power modules 3, thus enabling lower-temperature air to be supplied downstream. Therefore, the power semiconductor device 101 according to the second embodiment can effectively suppress temperature increase in the power modules 3.

Furthermore, the power semiconductor device 101 according to the second embodiment enables the power modules 3 to be freely arranged within areas where the uneven surfaces 20a of the heat sink bases 20 are formed, thus allowing for greater design freedom and enhanced productivity of the heat sink-integrated power modules.

The housing 13 and the adapter plate 14 are formed as separate members and then joined together; however, the housing 13 and the adapter plate 14 may be integrally formed as a single member. The number of openings 14a is not limited to three, as illustrated, and may be two, four, or more. The shape of each opening 14a is not limited to a rectangular shape elongated in the direction X, which is orthogonal to the direction of the air flow A, and may be a rectangular shape elongated along the direction of the air flow A or another shape, such as a square. The number of power modules 3 provided on the single heat sink 2, which is an individual piece, is not limited to two, as illustrated, and may be one, three, or more.

### Third Embodiment

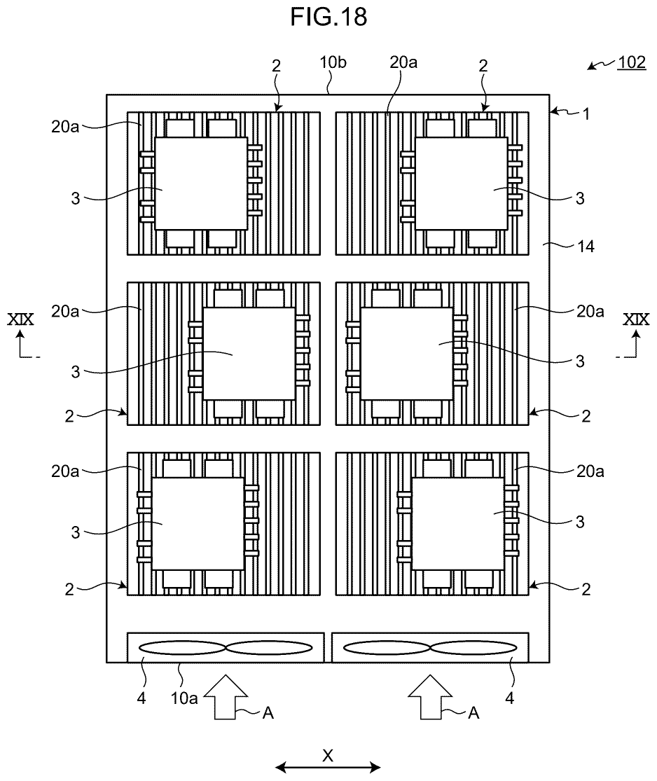

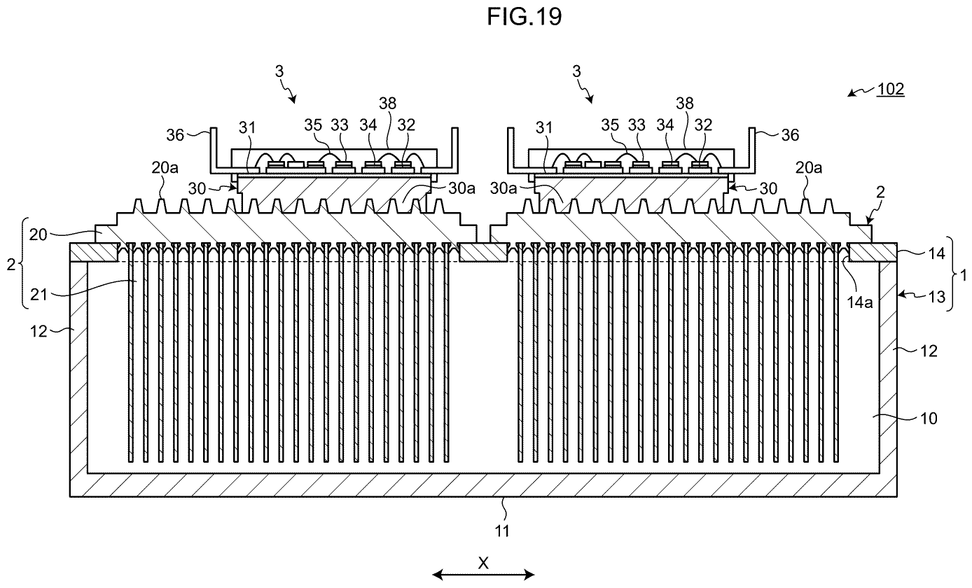

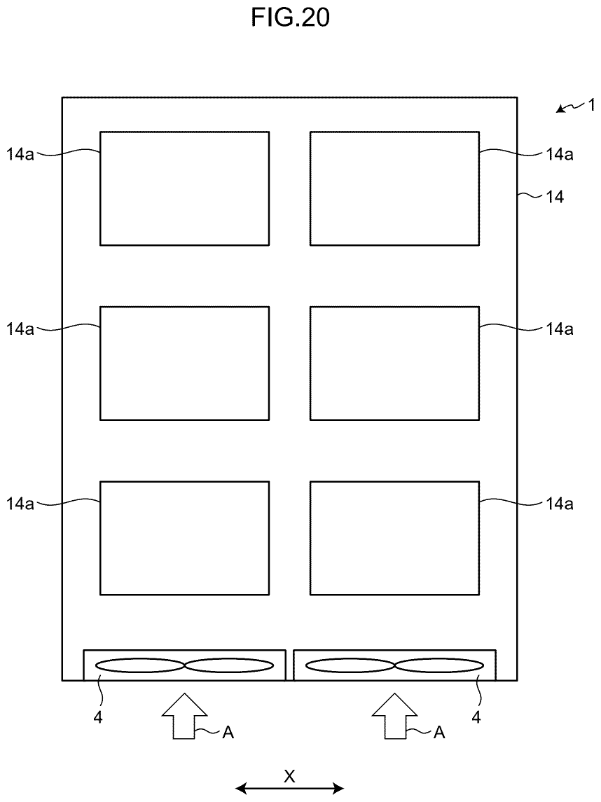

Next, a description of power semiconductor devices 102 and 102A according to a third embodiment is provided. FIG. 18 is a plan view illustrating a power semiconductor device according to the third embodiment. FIG. 19 is a cross-sectional view in the direction of arrows XIX-XIX in FIG. 18. FIG. 20 is a plan view illustrating an adapter plate of the power semiconductor device according to the third embodiment.

As illustrated in FIGS. 18 to 20, a case 1 of the power semiconductor device 102 according to the third embodiment has a configuration in which a plurality of openings 14a are formed at intervals along the direction of the air flow A in a face defining the air passage 10. Specifically, the case 1 includes the housing 13, which has the recessed shape formed by the bottom part 11 and the pair of side walls 12; and the adapter plate 14 that is disposed facing the bottom part 11 and covers the open face of the housing 13. The case 1, formed by the housing 13 and the adapter plate 14, has the shape of a rectangular tube. The case 1 has open ends extending along the direction of the air flow A. One of the open ends serves as the inlet 10a for the air flow A, which is blown by the cooling fans 4, and the other open end serves as the outlet 10b for the air flow A. The air passage 10 is a space surrounded by the housing 13 and the adapter plate 14. In the example illustrated in FIG. 18, the direction of the air flow A is from the inlet 10a to the outlet 10b; however, this is not limiting. The air flow A may be in an opposite direction, from the outlet 10b to the inlet 10a, with the outlet 10b serving as an inlet and the inlet 10a, where the cooling fans 4 are disposed, serving as an outlet.

The housing 13 and the adapter plate 14 are each formed of a plated steel plate. The plated steel plate is rigid enough to hold heat sinks 2 integrated with the plurality of power modules 3 and is a material that allows for thickness reduction and weight reduction. The housing 13 and the adapter plate 14 may each be formed of a material other than a plated steel plate.

The adapter plate 14 has peripheral edges placed on the upper end faces of the side walls 12 and is fixed to the side walls 12 by joining members (not illustrated), such as screws. The side walls 12 are provided with threaded holes (not illustrated) for the screws or other joining members to be screwed in. The adapter plate 14 is provided with threaded or through holes (not illustrated) at positions corresponding to the threaded holes in the side walls 12.

The plurality of openings 14a are formed in the adapter plate 14 at intervals along the direction of the air flow A. The plurality of openings 14a are arranged in a plurality of columns. In the third embodiment, the openings 14a are formed, for example, in a two-column-by-three-row arrangement and are aligned along the direction of the air flow A. As illustrated in FIG. 20, each of the openings 14a has, for example, a rectangular shape that is elongated in the direction X, which is orthogonal to the direction of the air flow A.

As illustrated in FIG. 18, the heat sinks 2 are provided as individual pieces corresponding respectively to the openings 14a. As illustrated in FIG. 19, each of the heat sinks 2 is supported by the case 1, with its fins 21 inserted through the opening 14a and disposed in the air passage 10. Each heat sink 2 is formed to in accordance with size and the shape of the opening 14a. Each heat sink base 20 has its peripheral edges placed on an upper face of the adapter plate 14, with the fins 21 inserted through the opening 14a and disposed in the air passage 10, and is fixed to the adapter plate 14 by joining members (not illustrated), such as screws. The adapter plate 14 is provided with threaded holes (not illustrated) for the screws or other joining members to be screwed in. Each heat sink base 20 is provided with threaded or through holes (not illustrated) at positions corresponding to the threaded holes in the adapter plate 14.

Each of the heat sinks 2 that are individually provided is integrally provided with one power module 3. In other words, the power semiconductor device 102 according to the third embodiment is configured by omitting part of the heat sink 2 from the configuration of the first embodiment, thereby enabling weight reduction of the device. Furthermore, the power semiconductor device 102 according to the third embodiment allows for improved maintainability because when a power module 3 fails, only the heat sink 2 on which the failed power module 3 is mounted needs to be replaced.

In the power semiconductor device 102 according to the third embodiment as well, one of an adjacent pair of the power modules 3 in the direction of the air flow A is disposed to offset in the direction X, which is orthogonal to the direction of the air flow A, relative to the other of the adjacent pair of the power modules 3. Specifically, among three power modules 3 provided along the direction of the air flow A, the middle power module 3 is disposed to offset in the direction X, which is orthogonal to the direction of the air flow A, relative to the most upstream power module 3 and the most downstream power module 3.

With this configuration, the power semiconductor device 102 according to the third embodiment can reduce cumulative thermal interference and, therefore, makes it less likely for the semiconductor elements 33 of the downstream power modules 3 to be affected by heat generated by the semiconductor elements 33 of the upstream power modules 3, thus enabling lower-temperature air to be supplied downstream. Therefore, the power semiconductor device 102 according to the third embodiment can effectively suppress temperature increase in the power modules 3.

Furthermore, the power semiconductor device 102 according to the third embodiment enables the power modules 3 to be freely arranged within areas where the uneven surfaces 20a of the heat sink bases 20 are formed, thus allowing for greater design freedom and enhanced productivity of the heat sink-integrated power modules.

The housing 13 and the adapter plate 14 are formed as separate members and then joined together; however, the housing 13 and the adapter plate 14 may be integrally formed as a single member. The number of openings 14a is not limited to six, as illustrated; each column only needs to have at least two. The shape of each opening 14a is not limited to a rectangular shape elongated in the direction X, which is orthogonal to the direction of the air flow A, and may be a rectangular shape elongated along the direction of the air flow A or another shape, such as a square.

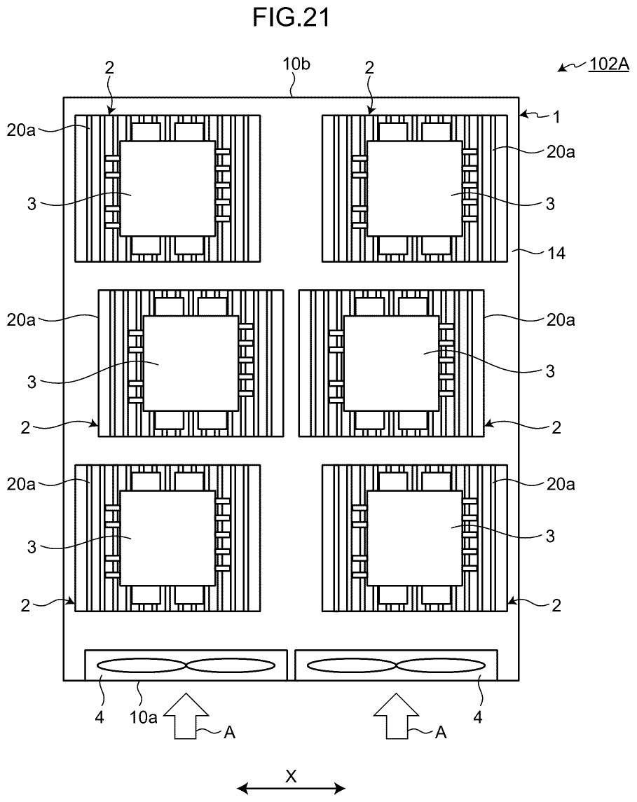

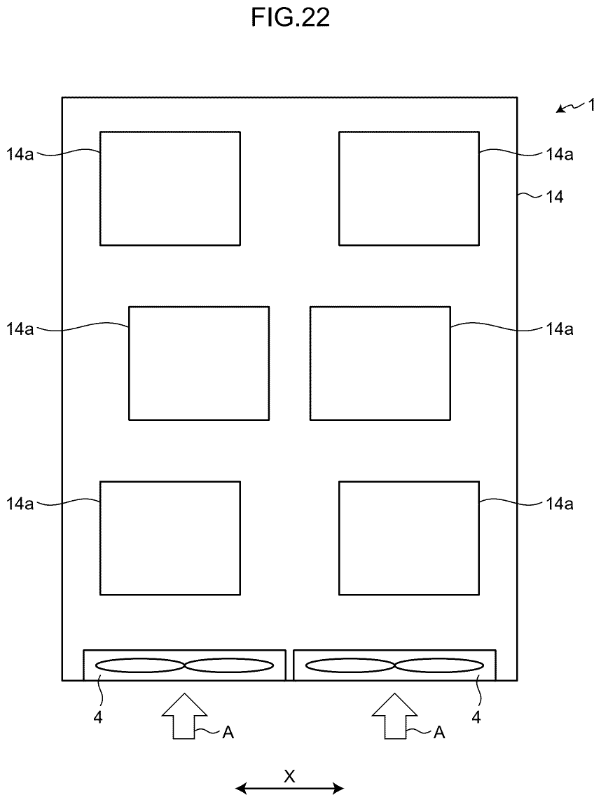

FIG. 21 is a plan view illustrating a variation of the power semiconductor device according to the third embodiment. FIG. 22 is a plan view illustrating an adapter plate of the variation of the power semiconductor device according to the third embodiment. The power semiconductor device 102A illustrated in FIGS. 21 and 22 has a configuration in which one of an adjacent pair of the openings 14a in the direction of the air flow A is formed to offset in the direction X, which is orthogonal to the direction of the air flow A, relative to the other of the adjacent pair of the openings 14a. Specifically, among three openings 14a formed along from the inlet 10a to the outlet 10b, the middle opening 14a is formed to offset in the direction X, which is orthogonal to the direction of the air flow A, relative to the most upstream opening 14a and the most downstream opening 14a.

With this configuration, one of an adjacent pair of the power modules 3 in the direction of the air flow A can be disposed to offset in the direction X, which is orthogonal to the direction of the air flow A, relative to the other of the adjacent pair of the power modules 3, simply by fitting and installing the heat sink-integrated power modules of the same structure respectively into the openings 14a of the adapter plate 14.

### Fourth Embodiment

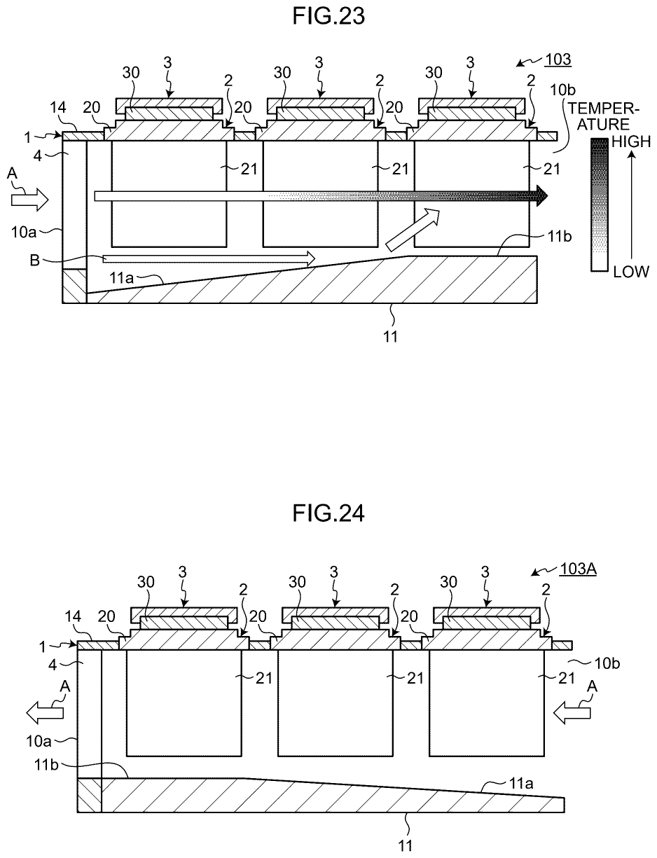

Next, a description of power semiconductor devices 103, 103A, and 103B according to a fourth embodiment is provided. FIG. 23 is a longitudinal sectional view schematically illustrating a power semiconductor device according to the fourth embodiment. As illustrated in FIG. 23, a case 1 of the power semiconductor device 103 according to the fourth embodiment has a bottom part 11 that is configured differently from those described in the second and third embodiments. The power semiconductor device 103 is otherwise similar in configuration to those described in the second and third embodiments. In the fourth embodiment, in a face of the case 1 that defines an air passage 10, the plurality of openings 14a are formed at intervals along the direction of the air flow A. The heat sinks 2 are provided as individual pieces corresponding respectively to the openings 14a, and each of the heat sinks 2 is supported by the case 1, with its fins 21 inserted through the opening 14a and disposed in the air passage 10.

As illustrated in FIG. 23, the case 1 includes, on the bottom part 11 that faces the fins 21 of the heat sinks 2, a sloped face 11a that comes closer to the fins 21 as the sloped face 11a extends from the inlet 10a, which defines one end, toward the outlet 10b, which defines an opposite end, in the direction of the air flow A. The sloped face 11a is formed to extend from the inlet 10a to just in front of the most downstream heat sink-integrated power modules and then connects with a horizontal face 11b that extends to the outlet 10b in parallel with the fins 21. In other words, the air passage 10 is shaped such that its cross-sectional area decreases as the air passage 10 extends from an upstream side toward a downstream side, reaches a minimum just in front of the most downstream heat sink-integrated power modules, and then remains at that minimum up to the outlet 10b. The horizontal face 11b does not need to be strictly horizontal and may be slightly inclined as long as the horizontal face 11b is generally horizontal.

This configuration enables a larger quantity of air flow B that passes between the bottom part 11 and the fins 21 with almost no temperature increase to be introduced between the fins 21 of the downstream heat sink(s) 2, thereby effectively reducing temperature increase in the downstream power modules 3. The sloped face 11a is not limited to the configuration in which the sloped face 11a extends from the inlet 10a to just in front of the most downstream heat sink-integrated power modules and may be formed to extend only up to just in front of the middle heat sink-integrated power modules. The sloped face 11a may, for example, be formed continuously from the inlet 10a to the outlet 10b or may be combined with horizontal faces 11b to form a stepped slope.

FIG. 24 is a longitudinal sectional view schematically illustrating Variation 1 of the power semiconductor device according to the fourth embodiment. In the power semiconductor device 103A illustrated in FIG. 24, a bottom part 11 that faces the fins 21 of the heat sinks 2 includes a sloped face 11a that comes closer to the fins 21 as the sloped face 11a extends from the outlet 10b, which defines one end, toward the inlet 10a, which defines an opposite end, in a direction of the air flow A. In other words, the direction of the air flow A in the power semiconductor device 103A illustrated in FIG. 24 is opposite to that in the power semiconductor device 103 illustrated in FIG. 23.

Thus, even the power semiconductor device 103A illustrated in FIG. 24 enables a larger quantity of air that flows between the bottom part 11 and the fins 21 with almost no temperature increase to be introduced between the fins 21 of the downstream heat sink(s) 2, thereby effectively reducing heat generated by the downstream power modules 3.

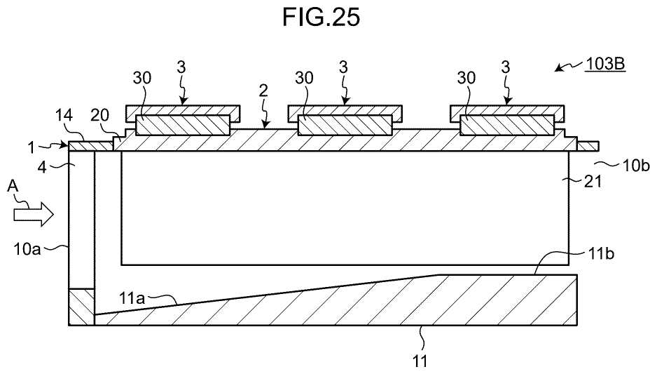

FIG. 25 is a longitudinal sectional view schematically illustrating Variation 2 of the power semiconductor device according to the fourth embodiment. The power semiconductor device 103B illustrated in FIG. 25 is obtained by applying the features of the fourth embodiment described with reference to FIG. 23 to the configuration of the first embodiment. In other words, the power semiconductor device 103B is configured to include the sloped face 11a on the bottom part 11 of the case 1, with the plurality of power modules 3 provided on the single heat sink 2. Although not illustrated, the sloped face 11a of the power semiconductor device 103A illustrated in FIG. 24 may be applied to the configuration of the first embodiment.

The above configurations illustrated in the embodiments are illustrative, can be combined with other techniques that are publicly known, and can be partly omitted or changed without departing from the gist. The embodiments can be combined with each other.

### REFERENCE SIGNS LIST

1 case; 2 heat sink; 3 power module; 4 cooling fan; 10 air passage; 10a inlet; 10b outlet; 11 bottom part; 11a sloped face; 11b horizontal face; 12 side wall; 13 housing; 14 adapter plate; 14a opening; 20 heat sink base; 20a uneven surface; 21 fin; 30 fin base; 30a uneven part; 31 insulator; 32 metal conductor; 33 semiconductor element; 34 bonding material; 35 wiring wire; 36 control terminal; 37 main terminal; 38 encapsulant; 100, 100A, 100B, 101, 102, 102A, 103, 103A, 103B power semiconductor device; A, B air flow.

1. A power semiconductor device comprising:
a case including an air passage, with an inlet and an outlet for an air flow facing each other;
a heat sink including:
a plate-shaped heat sink base; and
a plate-shaped plurality of fins and arranged in parallel at intervals on one face of the heat sink base, the heat sink being held by the case, with the fins disposed in the air passage; and
a plurality of power modules provided on an opposite face of the heat sink base, wherein
an uneven surface is formed on the opposite face of the heat sink base,
the power modules each include an uneven part engaging with the uneven surface of the heat sink base and are spaced along a direction of the air flow, with the uneven parts fitted into the uneven surface of the heat sink base, and
one of an adjacent pair of the power modules in the direction of the air flow is disposed to offset in a direction orthogonal to the direction of the air flow relative to an other of the adjacent pair of the power modules within an area where the uneven surface of the heat sink base is formed.

2. The power semiconductor device according to claim 1, wherein
the uneven surface formed includes recesses and projections that extend along the direction of an air flow.

3. The power semiconductor device according to claim 1, wherein
the uneven surface formed includes recesses and projections that extend in a direction intersecting the direction of an air flow.

4. The power semiconductor device according to claim 2, wherein
the recesses and projections are each formed continuously or at intervals along an extending direction of the recesses and the projections.

5. The power semiconductor device according to claim 1, wherein
the uneven surface includes dot-shaped protrusions arranged in rows.

6. The power semiconductor device according to claim 1, wherein
the case includes a plurality of openings formed at intervals along the direction of the air flow in a face defining the air passage, and
heat sinks are provided as individual pieces corresponding respectively to the openings, and each of the heat sinks is supported by the case, with the fins inserted through the openings and disposed in the air passage.

7. The power semiconductor device according to claim 6, wherein
the openings are formed and aligned along the direction of the air flow.

8. The power semiconductor device according to claim 6, wherein
one of an adjacent pair of the openings in the direction of the air flow is formed to offset in a direction orthogonal to the direction of the air flow relative to another of the adjacent pair of the openings.

9. The power semiconductor device according to claim 6, wherein
each of the heat sinks that are individually provided is equipped with one of the power modules.

10. The power semiconductor device according to claim 6, wherein
the openings that are spaced along the direction of the air flow are arranged in a plurality of columns.

11. The power semiconductor device according to claim 1, wherein
the case includes, on a bottom part that faces the fins of the heat sinks, a sloped face that comes closer to the fins as the sloped face extends from one end toward an opposite end in the direction of the air flow.

12. The power semiconductor device according to claim 3, wherein
the recesses and projections are each formed continuously or at intervals along an extending direction of the recesses and the projections.
